(19) United States
(12) Patent Application Publication
(10) Pub. No.: US 2024/0363368 A1
(43) Pub. Date: Oct. 31, 2024

(54) SENSOR PACKAGE AND METHOD FOR FORMING THE SAME

(71) Applicant: STATS ChipPAC Pte. Ltd., Singapore (SG)

(72) Inventors: MyungHo JUNG, Gyeonggi-do (KR); BumRyul MAENG, Incheon (KR)

(21) Appl. No.: 18/646,867

(22) Filed: Apr. 26, 2024

(30) Foreign Application Priority Data
Apr. 28, 2023 (CN) 202310486278.3

(51) Int. Cl. H01L 21/56; G01S 7/481; H01L 23/31; H01L 23/498; H01L 25/16

(52) U.S. Cl. CPC H01L 21/56; G01S 7/4813; H01L 23/3121; H01L 23/49811; H01L 25/16

(57) ABSTRACT

A method for forming a sensor package, comprising: providing a substrate, wherein one or more connectors are attached onto a front side of the substrate; forming an encapsulant layer on the front side of the substrate, wherein the one or more connectors are exposed from the encapsulant layer; forming a sacrificial layer on the encapsulant layer, wherein a periphery of the sacrificial layer is smaller than a periphery of the encapsulant layer, and wherein the sacrificial layer is molded as including a base portion, a step portion with a periphery smaller than a periphery of the base portion, and at least one extrusion portion on the base portion; applying an encapsulant material surrounding the base portion of the sacrificial layer, to enlarge the encapsulant layer; removing the sacrificial layer from the encapsulant layer, to form a cavity corresponding to the step portion and the base portion of the sacrificial layer, and to form at least one hole corresponding to the at least one extrusion portion on the enlarged encapsulant layer; positioning a sensor within the cavity and connecting the sensor to the one or more connectors; and attaching a cap onto the enlarged encapsulant layer to cover the cavity.

### TECHNICAL FIELD

The present application generally relates to semiconductor packaging technology, and more particularly, to a sensor package and a method for forming a sensor package.

### BACKGROUND OF THE INVENTION

Recently, electric vehicle and automatic driving technologies are rapidly developing. Sensors such as lidar sensors are commonly used in automatic driving for detecting environment around a vehicle. The sensors are usually integrated into a semiconductor package with electronic components with other functionalities to make the entire semiconductor package smaller.

The automatic driving technology requires a very high level of reliability. However, current sensor packages may have a risk of moisture penetration through a lid of the sensor package, which may cause damages to the sensor packages and significantly impact the reliability of the sensor packages.

Therefore, a need exists for further improvement to sensor packages.

### SUMMARY OF THE INVENTION

An objective of the present application is to provide a sensor package with improved reliability and a method for forming the sensor package.

According to one aspect of the present application, a method for forming a sensor package is provided. The method comprising: providing a substrate, wherein one or more connectors are attached onto a front side of the substrate; forming an encapsulant layer on the front side of the substrate, wherein the one or more connectors are exposed from the encapsulant layer; forming a sacrificial layer on the encapsulant layer, wherein a periphery of the sacrificial layer is smaller than a periphery of the encapsulant layer, and wherein the sacrificial layer is molded as including a base portion, a step portion with a periphery smaller than a periphery of the base portion, and at least one extrusion portion on the base portion; applying an encapsulant material surrounding the base portion of the sacrificial layer, to enlarge the encapsulant layer; removing the sacrificial layer from the encapsulant layer, to form a cavity corresponding to the step portion and the base portion of the sacrificial layer, and to form at least one hole corresponding to the at least one extrusion portion on the enlarged encapsulant layer; positioning a sensor within the cavity and connecting the sensor to the one or more connectors; and attaching a cap onto the enlarged encapsulant layer to cover the cavity.

According to another aspect of the present application, a sensor package is provided. The sensor package comprises: a substrate; one or more electronic components formed on a front side of the substrate; one or more connectors on the front side of the substrate; an encapsulant layer on the front side of the substrate, wherein the encapsulant layer includes a cavity and at least one hole on a front side of the encapsulant layer, and wherein the one or more connectors are exposed in the cavity; a sensor within the cavity, wherein the sensor is connected with the one or more connectors; and a cap on the encapsulant layer to cover the cavity.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A and FIG. 1B are respectively a sectional view and a top view showing a sensor package according to an embodiment of the present application.

FIG. 2 is a flow chart of a method for forming a sensor package according to an embodiment of the present application.

FIG. 3A to FIG. 3K are sectional views showing various steps of a method for forming a sensor package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

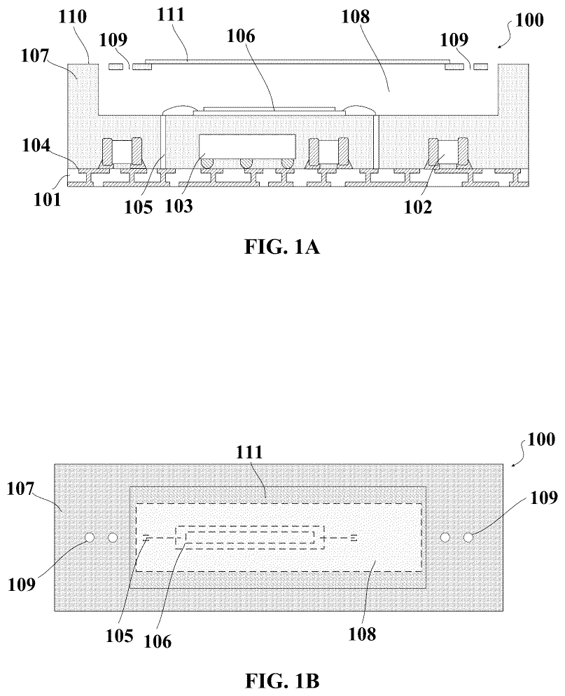

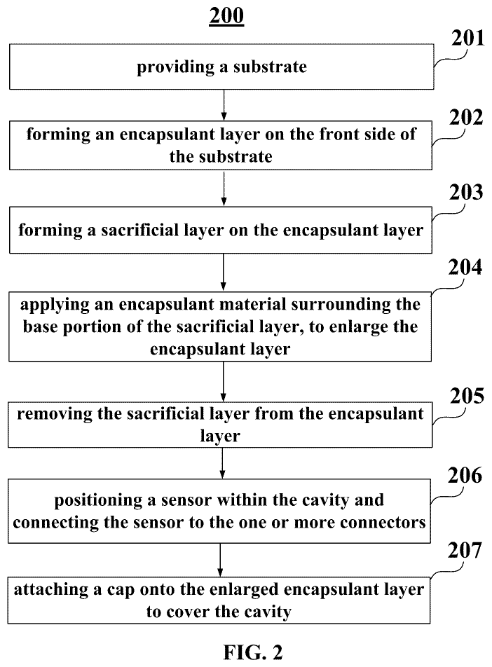

FIGS. 1A and 1B illustrate a sensor package 100 according to an embodiment of the present application. In particular, FIG. 1B is a top view of the sensor package 100, and FIG. 1A is a sectional view of the sensor package 100.

As shown in FIG. 1A and FIG. 1B, the sensor package 100 includes a substrate 101. In some embodiments, the substrate 101 may be a printed circuit board (PCB), a laminate interposer, a strip interposer, a leadframe, or another suitable substrate. The substrate 101 may include one or more insulating or passivation layers, one or more conductive vias formed through the insulating layers, and one or more conductive layers formed over or between the insulating layers. The substrate 101 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, or other reinforcement fibers or fabrics. The substrate 101 may also be a multi-layer flexible laminate, ceramic, copper clad laminate, glass, or semiconductor wafer including an active surface containing one or more transistors, diodes, and other circuit elements to implement analog circuits or digital circuits. The substrate 101 may include one or more electrically conductive layers or redistribution layers (RDL) formed using sputtering, electrolytic plating, electroless plating, or other suitable deposition process. The conductive layers may be one or more layers of Al, Cu, Sn, Ni, Au, Ag, Ti, W, or other suitable electrically conductive material. In some embodiments, one or more conductive patterns may be exposed from the surface of the substrate 101, and subsequently connected with solder balls or the like for subsequent mounting or connecting of other components or devices.

The sensor package 100 may further include one or more electronic components, such as one or more passive devices 102 (e.g., capacitors or resistors) or one or more semiconductor dice 103, mounted on a front side 104 of the substrate 101. The sensor package 100 may also include one or more connectors 105 on the front side 104 of the substrate 101, to connect a sensor 106 of the sensor package 100 to the substrate 101. In some embodiments, the connectors 105 may be metal posts or metal pillars such as copper posts or pillars. In some other embodiments, the connectors 105 may be solder bumps or e-bar connectors. In some embodiments, the sensor 106 may be a lidar sensor, an image sensor, a pressure sensor or any other suitable sensors.

An encapsulant layer 107 is formed on the front side 104 of the substrate 101, to cover the one or more electronic components 102 and 103 and the connectors 105, and prevent them from damages, shock or contaminants. The encapsulant layer 107 may define a cavity 108, to accommodate the sensor 106. In addition, with the cavity 108, the sensor 106 can be easily positioned into the sensor package 100 during manufacturing, which will be discussed in detail below. In the embodiment, the sensor 106 can be positioned within the cavity 108 and attached onto a bottom surface of the cavity. Furthermore, the sensor 106 may be electrically coupled to the connectors 105 on the substrate 101 through bonding wires, for example. Therefore, the sensor 106 can be electrically connected with the other components of the sensor package 100 to form an integrated device. In that case, the connectors 105 may have a height greater than that of the various components such as the electronic components 102 and 103 encapsulated within the encapsulant layer 107.

Further, as shown in FIGS. 1A and 1B, the sensor package 100 may include one or more air vent holes 109 to, for example, dissipate heat generated during operation of the sensor package 100. However, since the senor package 100 may be used in automatic driving vehicles or other devices which may require a high level of reliability, it is desired that the air vent holes 109 have no risk or very low risk of moisture penetration. Otherwise, the penetrated moisture may misfunction the sensor 106 of the sensor package 100. In some embodiments, the encapsulant layer 107 of the sensor package 100 includes several holes 109 on a front side 110 of the encapsulant layer 107, which serve as the air vent holes. It can be appreciated that though the sensor package 100 is shown as including four holes 109 on the front side 110 of the encapsulant layer 107 as air vent holes, any other number of holes may be formed on the front side of the encapsulant layer 107 based on practical needs. Furthermore, the holes may be formed on other sides of the encapsulant layer 107 in another layout.

As aforementioned, the air vent holes may dissipate heat or allow for ventilation between the cavity 108 inside the sensor package 100 and the environment external to the sensor package 100, but moisture is desired not to pass through the air vent holes into the cavity 108. The inventors of the present application have conducted experiments on various sized air vent holes to identify the relationship between the diameter of the air vent holes of the encapsulant layer and the water pressure resistance for the holes. Based on the experiments conducted by the inventors of the present application, sensor packages having air vent holes with a diameter of 10 μm can resist a water pressure of about 11 kPa, which corresponds to a water depth of about 110 cm; sensor package having air vent holes with a diameter of 15 μm can resist a water pressure of about 7.5 kPa, which corresponds to a water depth of about 75 cm; and a sensor package having air vent holes with a diameter of 20 μm can resist a water pressure of about 4.5 kPa, which corresponds to a water depth of about 45 cm. Sensor packages having air vent holes with a larger diameter may resist a less water pressure. In some embodiments, to ensure that the sensor packages can be waterproof at a water depth of over 1 m, the sensor packages may have air vent holes with a diameter of 10 μm or less.

Still referring to FIG. 1A, the sensor package 100 may further include a cap 111, which covers the top opening of the cavity 108, to provide protection for the sensor 106 positioned within the cavity 108. In some embodiments, the sensor package 100 is a lidar sensor package and the sensor 106 is a lidar sensor. In that embodiment, the cap 111 may be a light transparent optical filter for filtering lights transmitted from the surrounding environment to the lidar sensor 106 and from the lidar sensor 106 to surrounding environment. In some other embodiments, the sensor 106 may be an ultrasonic sensor or a pressure sensor, and therefore, the cap 111 may be either transparent to light or opaque to light. In some embodiments, the cap 111 may be made of glass, polymer or any other suitable materials.

FIG. 2 is a flow chart of a method 200 for forming a sensor package according to an embodiment of the present application, for example, for forming the sensor package 100 as shown in FIG. 1 or a similar sensor package.

The method 200 may start with step 201, and a substrate is provided. At step 202, an encapsulant layer is formed on the front side of the substrate, and at step 203, a sacrificial layer is formed on the encapsulant layer. Next, at step 204, an encapsulant material is applied surrounding the base portion of the sacrificial layer to enlarge the encapsulant layer. At step 205, the sacrificial layer is removed from the encapsulant layer. At step 206, a sensor is positioned within the cavity and the sensor is connected to the one or more connectors. Afterwards, at Step 207, a cap is attached onto the enlarged encapsulant layer to cover the cavity.

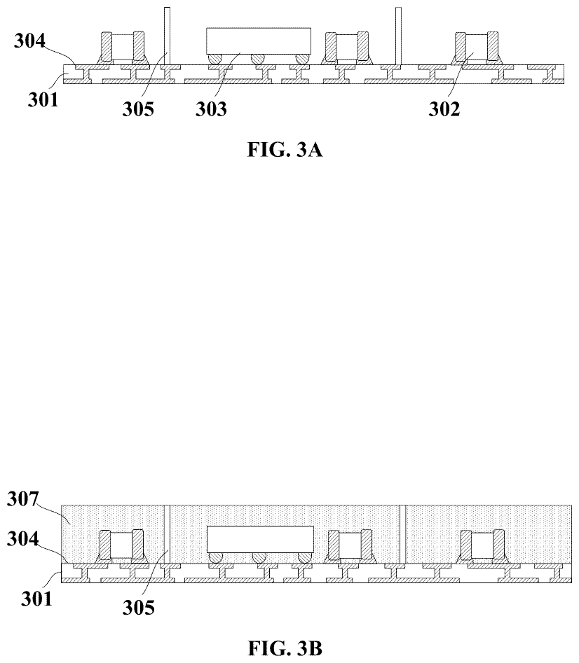

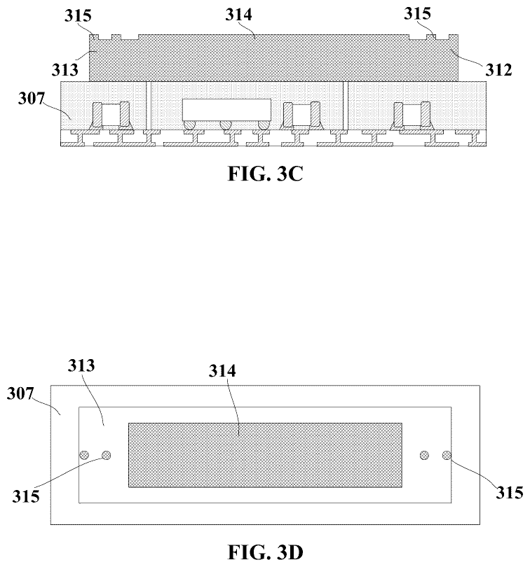

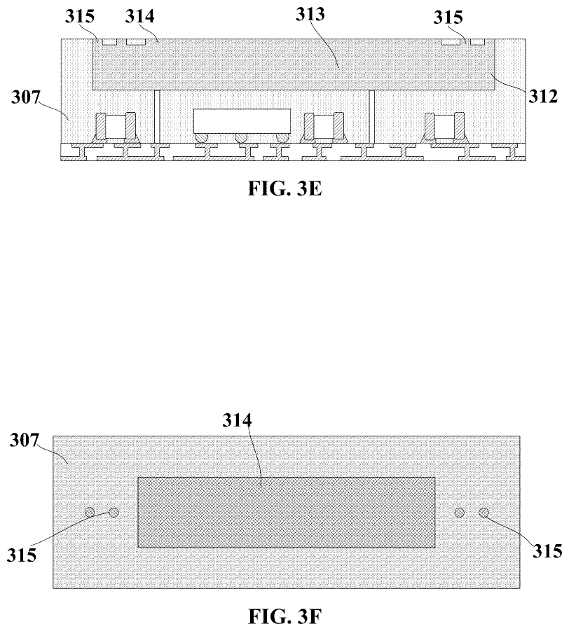

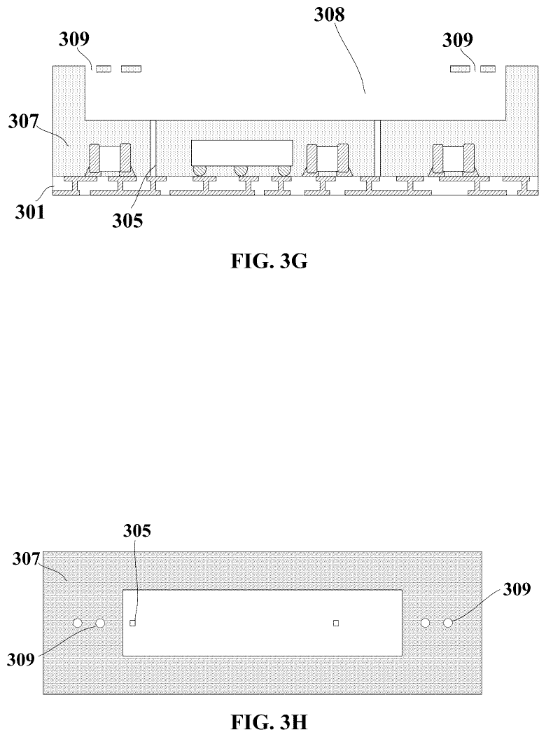

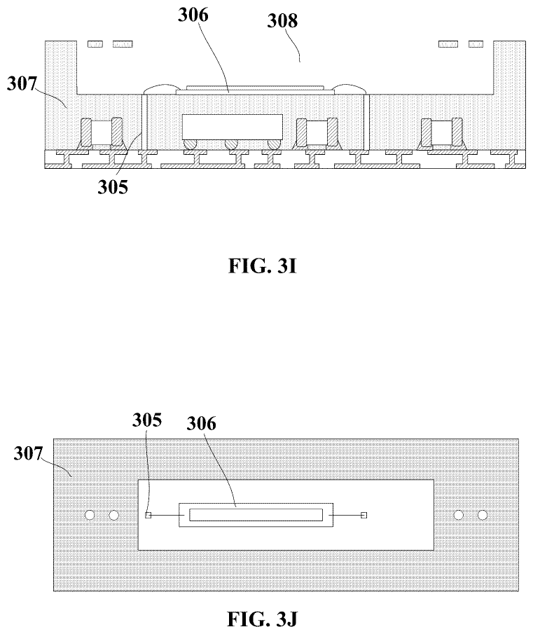

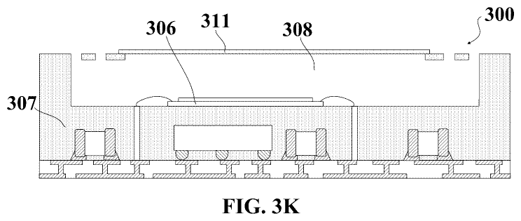

FIGS. 3A to 3K are sectional views showing various steps of a method for forming a sensor package according to an embodiment of the present application.

As shown in FIG. 3A, a substrate 301 is provided. One or more electronic components such as one or more passive devices 302 (e.g., capacitors or resistors) and one or more semiconductor dice 303 may be attached onto a front side 304 of the substrate 301, and one or more connectors 305 may also be attached onto the front side 304 of the substrate 301. In some embodiments, the connectors 305 may be metal posts or metal wires. The connector 305 may have a height greater than the heights of the semiconductor dice 303 and the passive devices 302. It can be appreciated that another number of electronic components may be mounted on the substrate 301, either on the same side or on both sides of the substrate 301.

Next, as shown in FIG. 3B, an encapsulant layer 307 is formed on the front side 304 of the substrate 301. The encapsulant layer 307 may be consisted of an encapsulant material. In some embodiments, the encapsulant layer 307 may be formed using a compression molding process or an injection molding process. In some other embodiments, the encapsulant layer 307 may be formed using paste printing, transfer molding, liquid encapsulant molding, vacuum lamination, spin coating, or other suitable process. The encapsulant layer 307 may be made of polymer composite material, such as epoxy resin with filler, epoxy acrylate with filler, or polymer with proper filler, but the scope of this application is not limited thereto. As shown in FIG. 3B, the connectors 305 can be exposed from the encapsulant layer 307, for connecting a sensor of the sensor package to the substrate 301, which will be discussed in detail below.

In some embodiments, the encapsulant layer 307 may be first formed on the first side 304 of the substrate 301, with excess encapsulant materials. Then, a portion of the encapsulant layer 307 may be grinded to expose the connectors 305 on the substrate 301, as shown in FIG. 3B.

Next, as shown in FIGS. 3C and 3D, a sacrificial layer 312 is formed on the encapsulant layer 307, for example, through deposition and lithography. In particular, the periphery of the sacrificial layer 312 is within the periphery of the encapsulant layer 307. That is, the sacrificial layer 312 is formed inside the encapsulant layer 307. In that case, the encapsulant layer 307 has a portion in its peripheral region that is not covered by the sacrificial layer 312. In some embodiments, the sacrificial layer 312 may include a photoresist material. The photoresist material may be coated on the encapsulant layer 307 and then patterned through lithography.

The sacrificial layer 312 may be formed as having a desired shape. As shown in FIG. 3C and FIG. 3D, the sacrificial layer 312 may be formed as including a base portion 313, a step portion 314 with a periphery smaller than a periphery of the base portion 313, and serval extrusion portions 315 extending from the base portion 313. The extrusion portions 315 of the sacrificial layer 312 are for forming air vent holes of the sensor package, for example, the air vent holes 109 as shown in FIG. 1A and FIG. 1B. Similarly, those skilled in the art can understand that though the sacrificial layer 312 is shown as including four extrusion portions 315, a sacrificial layer may include any number of extrusion portions based on practical needs, for example, including 1, 2, 3, 5 or more extrusion portions. Preferably, the extrusion portions 315 may have a diameter of 10 μm or less so that the corresponding air vent holes can have a diameter of 10 μm or less, therefore the final sensor package can be waterproof under water at a depth of one meter or even deeper.

Next, as shown in FIG. 3E and FIG. 3F, an encapsulant material is further applied surrounding the base portion 313 of the sacrificial layer 312, therefore the encapsulant layer 307 is enlarged to further surround the base portion 313 of the sacrificial layer 312. The encapsulant material may not be applied to cover the step portion 314 and the extrusion portions 315, so that air vent holes and a cavity can be formed in the final sensor package, which will be discussed in detail below.

Next, as shown in FIG. 3G and FIG. 3H, the sacrificial layer is removed from the enlarged encapsulant layer 307, for example, through chemical etching. By removing the sacrificial layer from the encapsulant layer 307, a cavity 308 corresponding to the step portion and the base portion of the sacrificial layer can be formed, to accommodate the sensor of the sensor package. Also, several holes 309 corresponding to the extrusion portions of the sacrificial layer are also formed in the enlarged encapsulant layer 307, which serve as air vent holes of the sensor package, similar as the holes 109 described with respect to FIG. 1. Since the sacrificial layer is removed, the connectors 305 which are previously covered by the sacrificial layer are exposed to connect the sensor of the package to the substrate 301. It can be appreciated that the encapsulant material which surrounds the base portion of the sacrificial layer can form a sidewall of the cavity 308, which will later be used for supporting a cap and form together with the cap a substantially water impermeable chamber.

Next, as shown in FIG. 3I and FIG. 3J, a sensor 306 is positioned within the cavity 308 of the encapsulant layer 307, and is connected to the connectors 305. Due to the step portion of the sacrificial layer which has been removed, the cavity 308 has an opening which allows for the positioning of the sensor 306 within the cavity 308. It can be appreciated that the sensor 306 generally has a footprint smaller than the previous sacrificial layer such that it can be placed within the cavity without significant interference with the encapsulant layer 307.

Afterwards, as shown in FIG. 3K, a cap 311 is positioned onto the enlarged encapsulant layer 307, to cover the cavity 308 and provide protection to the sensor 306. The cap 311 may be attached to the sidewall of the cavity 308 but do not cover the air vent holes. For example, the cap 311 may be attached to the sidewall of the cavity 308 using an adhesive material. As such, a sensor package 300 is finally formed. In some embodiments, the sensor package 300 is a lidar sensor package and the sensor 306 is a lidar sensor. In that embodiment, the cap 311 may be a transparent optical filter for filtering lights transmitted from surrounding environment to the lidar sensor 306.

With the method for forming a sensor package as disclosed in the present invention, air vent holes can be formed on the sensor package and also the sensor package can be waterproof so that the sensor package can have a satisfied reliability. In addition, through the method as disclosed in the present invention incorporated a molded sacrificial layer, the process for forming air vent air is convenient, and the number, size and pattern of the air vent holes can be easily controlled.

Further, compared with conventional process for forming a sensor package, the method disclosed in the present invention can easily control the thickness of the sensor package, for example, controlling the thickness of the encapsulant layer applied on the substrate. The method of the present invention can be used for forming a unit or an array of sensor packages, and then each sensor package can be singulated from the unit or array of sensor packages, therefore the production efficiency can be improved.

The discussion herein included numerous illustrative figures that showed various portions of a method for forming a shielding layer on a semiconductor device, and a semiconductor device with such formed shielding layer. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a sensor package, comprising:
providing a substrate, wherein one or more connectors are attached onto a front side of the substrate;
forming an encapsulant layer on the front side of the substrate, wherein the one or more connectors are exposed from the encapsulant layer;
forming a sacrificial layer on the encapsulant layer, wherein a periphery of the sacrificial layer is smaller than a periphery of the encapsulant layer, and wherein the sacrificial layer is molded as including a base portion, a step portion with a periphery smaller than a periphery of the base portion, and at least one extrusion portion on the base portion;
applying an encapsulant material surrounding the base portion of the sacrificial layer, to enlarge the encapsulant layer;
removing the sacrificial layer from the encapsulant layer, to form a cavity corresponding to the step portion and the base portion of the sacrificial layer, and to form at least one hole corresponding to the at least one extrusion portion on the enlarged encapsulant layer;
positioning a sensor within the cavity and connecting the sensor to the one or more connectors; and
attaching a cap onto the enlarged encapsulant layer to cover the cavity.

2. The method of claim 1, wherein before forming an encapsulant layer on the front side of the substrate, the method further comprises:
attaching one or more electronic components onto the front side of the substrate.

3. The method of claim 2, wherein the one or more electronic components are electrically coupled to the one or more connectors.

4. The method for claim 1, wherein forming an encapsulant layer on the front side of the substrate further comprises grinding a portion of the encapsulant layer to expose the one or more connectors.

5. The method for claim 1, wherein the sacrificial layer comprises a photoresist material.

6. The method for claim 5, wherein each of the at least one extrusion portion has a diameter of 10 μm or less.

7. The method for claim 1, wherein the sensor is a lidar sensor, and the cap is an optical filter.

8. A sensor package formed according to the method of claim 1.

9. A sensor package, comprising:
a substrate;
one or more electronic components formed on a front side of the substrate;
one or more connectors on the front side of the substrate;
an encapsulant layer on the front side of the substrate, wherein the encapsulant layer includes a cavity and at least one hole on a front side of the encapsulant layer, and wherein the one or more connectors are exposed in the cavity;
a sensor within the cavity, wherein the sensor is connected with the one or more connectors; and
a cap on the encapsulant layer to cover the cavity.

10. The sensor package of claim 9, wherein the at least one hole has a diameter of 10 μm or less.

11. The method for claim 9, wherein the sensor is a lidar sensor, and the cap is an optical filter.
